(19) United States
(12) Patent Application Publication
(10) Pub. No.: US 2009/0026656 A1
(43) Pub. Date: Jan. 29, 2009

(54) VENTED MOLD FOR ENCAPSULATING SEMICONDUCTOR COMPONENTS

(76) Inventors: Jesus Bajo Bautista, JR., Baguio City (PH); Victor Edgar Estioco Generosa, Baguio City (PH); Fausto Praza Raguindin, Baguio City (PH)

Correspondence Address: TEXAS INSTRUMENTS INCORPORATED, P O BOX 655474, M/S 3999, DALLAS, TX, 75265, US

(21) Appl. No.: 11/781,548

(22) Filed: Jul. 23, 2007

(51) Int. Cl. H01L 21/56

(52) U.S. Cl. 264/272.17; 425/405.1

(57) ABSTRACT

A mold system for forming a mold cap on a semiconductor component includes a mold base and a mold lid that together define a mold cavity. The mold base supports the semiconductor component within the mold cavity. The semiconductor component defines a component footprint and footprint periphery on the mold base. A supply channel is provided in the mold lid for supplying an encapsulating material to the mold cavity. At least one vent channel is provided in the mold base. The vent channel intersecting the footprint periphery to vent gas trapped between the semiconductor component and the mold base from the mold cavity when the encapsulating material is supplied to the mold cavity.

### BACKGROUND

Semiconductor devices, such as semiconductor dies, integrated circuit chips, and the like, can include a substrate or other semiconductor component that is at least partially covered with a mold cap made from a resin or other encapsulating substance. The semiconductor component may have one or more bridging wires or other structures that are encapsulated therewith to form a protected one-piece assembly.

The encapsulation procedure can be carried out by placing the semiconductor component on a mold base, lowering a concave mold lid onto the mold base to form a mold cavity at least partially enclosing the semiconductor component, and injecting the resin into the mold cavity. The resin is then allowed to at least partially harden within the mold cavity. The mold lid and mold base are separated once the resin is sufficiently set to allow removal of the now-encapsulated semiconductor component.

The amount of resin needed to encapsulate the semiconductor component can be minimized for advantages in cost, curing time, weight, and other considerations. Manufacturers have attempted to reduce a height of the mold cavity and thereby reduce the amount and height of resin needed to cover the semiconductor component. Such a reduction in height, however, can result in incomplete or improper encapsulation of the semiconductor components.

For example, during encapsulation, the semiconductor component may buckle and come into contact with the mold lid. A buckled semiconductor component usually cannot be properly encapsulated by the resin, particularly when the buckling causes the semiconductor component to contact the mold lid. In general, any semiconductor component with improper encapsulation is scrapped. Over time, these discarded semiconductor components can result in a substantial amount of wasted resources by the semiconductor manufacturer.

### SUMMARY

The present invention relates to a mold system for forming a mold cap on a semiconductor component. The mold system include a mold base and a mold lid that together define a mold cavity. The mold base supports the semiconductor component within the mold cavity. The semiconductor component defines a component footprint and footprint periphery on the mold base. A supply channel is provided in the mold lid for supplying an encapsulating material to the mold cavity. At least one vent channel is provided in the mold base. The vent channel intersects the footprint periphery to vent gas trapped between the semiconductor component and the mold base from the mold cavity when the encapsulating material is supplied to the mold cavity.

In an aspect of the invention, the vent channel provides a vacuum source in fluid communication with the mold cavity. The vacuum source urges the gas toward the vent channel. The vacuum source can also urge the semiconductor component into contact with the mold base when the gas has been substantially evacuated from between the semiconductor component and the mold base.

The present invention also relates to a method of encapsulating semiconductor components. In the method, a mold cavity between a mold lid and a mold base is defined. The semiconductor component is substantially enclosed within the mold cavity. A component footprint and a footprint periphery are defined on the mold base with the semiconductor component. At least one vent channel is located in at least one of the mold lid and the mold base. The vent channel intersects the footprint periphery. An encapsulating material is supplied to the mold cavity. Gas trapped between the semiconductor component and the mold base is vented from the mold cavity when the encapsulating material is supplied to the mold cavity.

### BRIEF DESCRIPTION OF THE DRAWINGS

FIG. 1A is a schematic sectional view of a mold system of the present invention in a first condition;

FIG. 1B is a schematic sectional view of a mold system of the present invention in a second condition;

FIG. 2 is a partial top plan view of a mold base of the present invention in a first configuration;

FIG. 3 is a cross-section taken along line 3-3 in FIG. 2;

FIG. 4 is a partial top plan view of the mold base of FIG. 2 in a second configuration; and

FIG. 5 is a partial top view of the embodiment of FIG. 2 in a third configuration.

### DETAILED DESCRIPTION

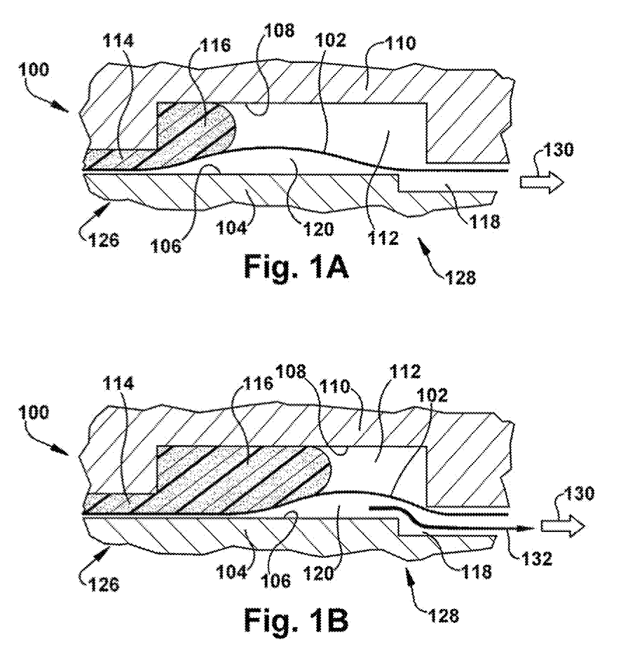

The present invention relates to a mold system for encapsulation of a semiconductor component. FIGS. 1A and 1B illustrate a mold system 100 for encapsulating a semiconductor component 102 in accordance with one aspect of the invention. An example of a semiconductor component 102 which can be encapsulated as set forth herein is a ball grid away (BGA) package (not shown). The ball grid array package includes a package substrate and a semiconductor chip that is attached to the package substrate. The package substrate can comprise an electrically insulative material, such as a flexible dielectric tape. The package substrate includes a first surface for mounting the semiconductor chip and a second surface. The substrate can be generally planar shaped and flat, such that the first surface faces in an opposite direction with respect to the second surface. The package substrate can include a conductive pattern (e.g., a copper pattern) comprising a plurality of conductive traces and conductive terminals that are formed on the chip mounting surface (i.e., the first surface) of the substrate. The conductive traces of the conductive pattern are electrically coupled to conductive vias. The conductive vias (i.e., through-holes filled with a conductive material) extend through the package substrate to an array of generally ball-shaped solder contacts (e.g., solder balls) that are formed on the second surface of the substrate and give the BGA package its name. The solder contacts can be used to form solder joints between the BGA package and a circuit board or an alternate level of interconnection. It is desirable to encapsulate at least a portion of the first surface with a mold cap to protect the semiconductor chip and/or other structures of the semiconductor component 102.

The mold system 100 for the semiconductor component 102, regardless of the type of semiconductor component, includes a mold base 104 that can support the semiconductor component. The mold base 104 defines a base surface 106 upon which at least a portion of the semiconductor component 102 is located adjacent to and/or rests upon.

A mold lid 110 is selectively moveable relative to the mold base 104 between a first, open position (not shown) and a second, closed position (as shown in FIGS. 1A and 1B). The mold lid 110 and mold base 104 may move in any desired manner. For example, the mold lid may be lowered downward (in the orientation of FIGS. 1A and 1B) onto the mold base 104. The mold lid 110 defines a lid surface 108 spaced apart from the base surface 106. The distance by which the lid surface 108 is spaced apart from the base surface 106 depends upon the height of the semiconductor component 102. For example, the spacing of the lid surface 108 and the base surface 106 is sufficient to space the semiconductor component 102, as well as any wires or protrusions associated therewith, a predetermined distance away from the lid surface 108 when the semiconductor component is resting upon the base surface 106.

The mold lid 110 and mold base 104 cooperatively define a mold cavity 112 therebetween when the mold lid 110 is in the second position. More specifically, the base surface 106 and lid surface 108 together at least partially enclose a space defined as the mold cavity 112, which substantially encloses the semiconductor component 102. At least a portion of the semiconductor component 102 may protrude from the mold cavity 112 when the mold lid 110 is in the second position. For example, the outer edges of the semiconductor component 102 may extend between the mold base 104 and the mold lid 110 adjacent the mold cavity 112 so that less than an entire surface of the semiconductor component 102 is encapsulated. Encapsulating less than the entire surface of the semiconductor component may provide sealing advantages for the mold cavity 112 and/or more secure positioning of the semiconductor component.

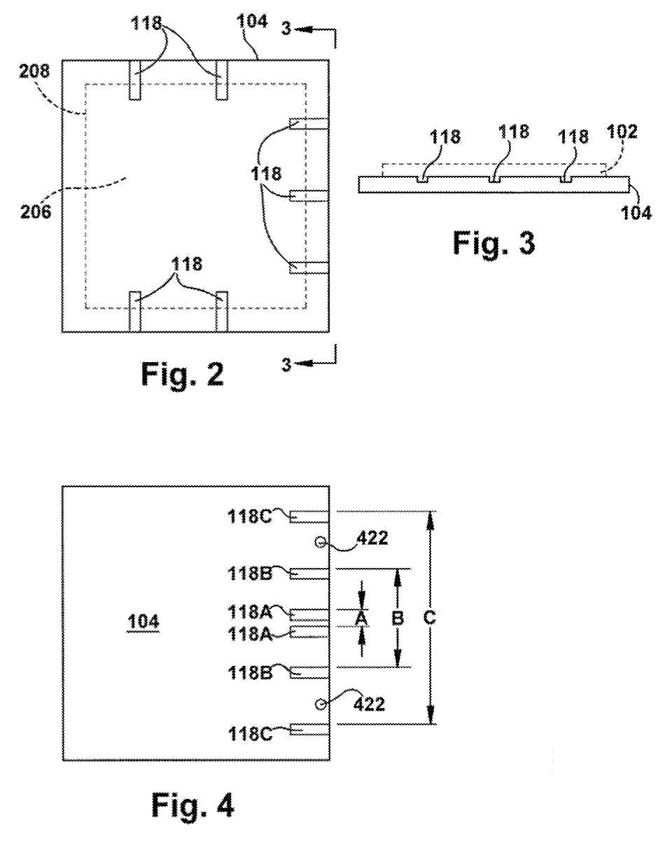

Referring to FIGS. 2 and 3, the semiconductor component 102 has a component footprint 206 that covers at least a portion of the mold base 104. The semiconductor component 102 need not be wholly in contact with the mold base 104 to completely define the component footprint 206 thereupon. The component footprint 206 can merely be that portion of the mold base 104 that is obscured by the semiconductor component 102 when viewed in plan view. A footprint periphery 208 extends around the component footprint 206. Portions of the semiconductor component 102 that extend outside the mold cavity 112 need not define the component footprint 206. In other words, the component footprint 206 can be defined by the smaller of the projection of the semiconductor component 102 and the area of the mold base 104 enclosed by the mold lid 110. When the semiconductor component 102 and/or the mold lid 110 are irregularly shaped or positioned offset from one another, the component footprint 206 may be defined by a combination of the semiconductor component 102 projection (namely, of those portions of the projection located within the mold cavity 112) and the mold lid 110 enclosure area.

Referring again to FIG. 21, a supply channel 114 is provided in the mold lid 110. Optionally, the supply channel 114 may be formed in the mold base 104 and/or the mold lid 110. The supply channel 114 is used to supply an encapsulating material 116 to the mold cavity 112. The encapsulating material 116 may be an electrically insulative molding compound, such as an epoxy-based material used in transfer molding, as well as potting materials, such as cyanate ester-type resins, epoxies, polyesters, polyimides, and cyanocrylates. The encapsulating material 116 can be strengthened by organic, and/or inorganic, fillers. It may be appreciated that other encapsulating materials 116 can also be used. The encapsulating material 116 is normally supplied to the mold cavity 112 in a known flowing manner, optionally under pressure.

At least one vent channel 118 is formed in the mold base 104 and is adapted to vent gas from the mold cavity 112. The vent channel 118 intersects the footprint periphery 208 at any location(s) of me component footprint 206, with a sample arrangement of vent channels shown in FIG. 2. Gas inside the mold cavity 112 may be a trapped ambient gas and/or may be gas generated by at least one of the semiconductor component 102 and the encapsulating material 116. For example, gas may be released from the semiconductor component 102 under clamping pressure from the mold system 100. Additionally, one or both of the semiconductor component 102 and the encapsulating material 116 may off gas within the mold cavity 112 in response to heat or chemical reactions during the encapsulating process. The gas between the semiconductor component 102 and the mold base 104 can be vented through the vent channel 118 to mitigate buckling of the semiconductor component 102 toward the mold lid 110. By mitigating buckling or warpage of the semiconductor component 102 during encapsulation wire bond failure on the semiconductor component 102 caused by contact of the buckled semiconductor component 102 with the mold lid 110 can be mitigated.

The vent channel 118 vents gas from the mold cavity 112 by providing a path for the gas to escape the mold cavity as the encapsulating material 116 fills the cavity. In the example first configuration of FIG. 2, a plurality of vent channels 118 are spaced at various locations around the footprint periphery 208 in an orthogonal arrangement with the footprint periphery 208. The orientation, configuration, number, location, and any other properties of the vent channel 118 may be readily determined by one of ordinary skill in the art for a particular application of the present invention and are not restricted to those shown and described herein. For example, the vent channels 118 need not be orthogonal to the footprint periphery 208 as shown, but may be arranged at any angle to the footprint periphery. One or more surfaces of the vent channel 118 can also be oriented at an angle to one or more other surfaces of the vent channel 118, as desired. The number, spacing, and location of the vent channels 118 may be chosen relative to the area and/or configuration of the component footprint 206. Sufficient vent channels 118 may be provided to vent the total desired amount of entrapped and generated gas from between the semiconductor component 102 and the base surface 106. For example, vent channels 118 could be provided to intersect between about 1 to about 90 percent of the footprint periphery 108.

Likewise, one of ordinary skill in the art can readily determine the desired sizes of the vent channels 118. For example, a vent channel 118 could be a rectilinear void, between about 0.1 to about 10 mm wide, e.g., about 1.0 mm wide; between about 5 to about 50 μm deep, e.g., about 15 μm deep; and between about 1 to about 100 mm long, e.g., about 10.0 mm long. Also, the footprint periphery 208 may intersect each vent channel 118 at any point along that vent channel 118, such as in a T-shaped intersection instead of the depicted X-shaped intersection. Moreover, the vent channel 118 can place the mold cavity 112 in fluid communication with another portion of the mold base 104 or with an ambient air surrounding the mold base.

Optionally, a vacuum source (not shown) may be placed in fluid communication with the mold cavity 112 through the vent channel 118 to provide active venting of the mold cavity 112. The vacuum source, when present, urges the gas toward the vent channel 118 from other areas within the mold cavity 112, such as from an air pocket 120 (shown in FIGS. 1A and 1B) beneath the semiconductor component 102. The vacuum source, operating cooperatively with the vent channel 118, can help prevent buckling of the semiconductor component 102 and mitigate encapsulation errors by reducing the size of the air pocket 120 beneath the semiconductor component as the encapsulating material 116 fills the mold cavity 112.

The vacuum source may also help prevent buckling of the semiconductor component 102, particularly when the semiconductor component 102 is flexible, by acting directly on the semiconductor component through the vent channel 118. To do so, the vacuum source urges the semiconductor component 102 into contact with the mold base 104 when the gas has been substantially evacuated from between the semiconductor component and the mold base. In such case, buckling caused by binding of the semiconductor component 102 on another structure of the mold system 100 may be avoided.

FIG. 3, a cross-sectional view taken along line 3-3 of FIG. 2, depicts an alternate view of the vent channels 118 in the first configuration of FIG. 2. As can be seen in FIG. 3, the vent channels 118 do not extend all the way through the depth of the mold base 104. FIG. 3 also shows that the vent channels 118 provide space beneath the semiconductor component 102, even when the semiconductor component is lying flat on the mold base 104. Such vertical spacing may facilitate the vacuum source in urging the semiconductor component 102 into contact with the mold base 104.

FIG. 4 depicts an example of a second configuration of vent channels 118. In this configuration, the vent channels 118 are located at one side of the mold base 104. The mold base 104 can includes one or more locating features, shown at 422, which engage mating features (not shown) on the semiconductor component 102 to hold the semiconductor component in position as desired. For example, one of the locating and mating features could be a pin and the other could be a hole adapted to receive the pin. The presence, location, and number of such locating features 422 can be readily determined by one of ordinary skill in the art. In the second configuration of FIG. 4, the vent channels 118 are arranged in pairs. The middle pair of vent channels 118A is spaced by a distance A, which may be between about 2-10 mm, e.g., about 4.5 mm. The intermediate pair of vent channels 118B is spaced by a distance B, which may be between about 10 to about 40 mm, e.g., about 21 mm. The outer pair of vent channels 118C is spaced by a distance C, which may be between about 25 to about 100 mm, e.g., about 45.5 mm.

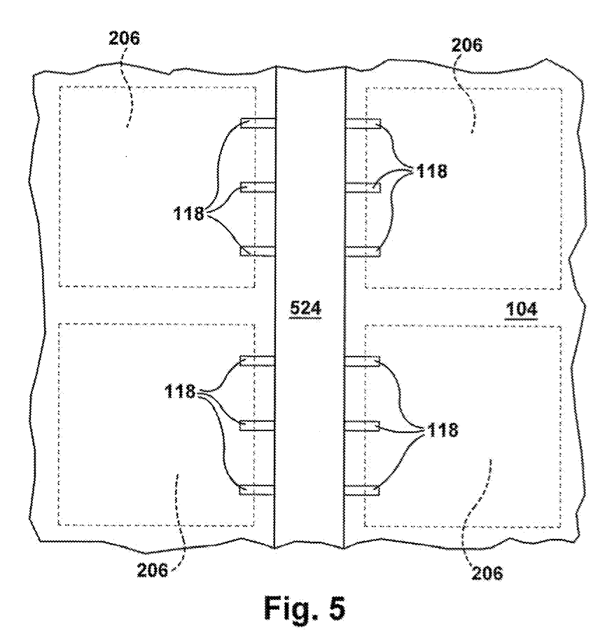

In another aspect of the invention as shown in FIG. 5, a single mold base 104 may be used to support a plurality of semiconductor components 102, each of which has a separate mold cavity 112 associated therewith, for mass production. A mold top (not shown) including a plurality of individual mold lids 110 is used in this type of multi-encapsulating mold system 100. In such an application, a system of internal passageways in the mold base 104 or mold top may allow encapsulating material 116 to be supplied to the plurality of mold cavities 112 substantially simultaneously, with resultant manufacturing efficiencies. The component footprints 206 of each of the plurality of semiconductor components 102 are shown in FIG. 5, with each component footprint 206 having at least one vent channel 118 associated therewith.

The mold base 104 includes a central venting line 524 that can be placed in fluid communication with the plurality of vent channels 118 for substantially simultaneous venting of each of the mold cavities 112 during the encapsulating process. The central venting line 524 may be passive, merely allowing gases to escape the mold cavities 112 through the vent channels 118, or may be active, connecting the vent channels 118 to a vacuum source (not shown). The central venting line 524 may be an enclosed passageway in the body of one or more of the mold base 104 or mold top, placed into fluid communication with one or more mold cavities 112. Alternately, and as shown in FIG. 5, the central venting line 524 may simply be a trough formed in the mold base 104, which may be enclosed, if desired, by a flat or trough-shaped portion in a corresponding location on the mold top.

Referring again to FIGS. 1A and 1B, the operation of the mold system 100 is described using a single mold cavity 112. It should be understood that a multiple-cavity mold system, such as that partially shown in FIG. 5, operates in a similar manner. To initially place the depicted components into the arrangement of FIGS. 1A and 1B, the semiconductor component 102 is first placed upon the base surface 106 and supported by the mold base 104. Then, the mold lid 110 is selectively moved from the first, open position to the second, closed position to create the mold cavity 112 as shown in FIGS. 1A and 1B. Optionally and as shown, a portion of the semiconductor component 102 may remain outside the mold cavity 112 once the mold lid 110 is placed in the closed condition.

In FIG. 1A, a first condition of the mold system 100 is depicted, in which encapsulating material 116 is starting to enter the mold cavity 112 from the supply channel 114. There may be any number of supply channels 114 provided, at any desired location in the mold base 104 and/or the mold lid 110, but a single supply channel 114 is depicted in the Figures, for clarity. The encapsulating material 116 may be of any type, and provided in any manner. The encapsulating material 116 is depicted herein as a viscous liquid flowing into the mold cavity 112 from a first mold cavity side 126 toward a second mold cavity side 128 spaced apart from the first mold cavity side, in a flow direction (arrow 130).

As the encapsulating material 116 begins to fill the mold cavity 112 and is directed through the mold cavity 112 by the structure thereof the semiconductor component 102 is forced down against the mold base 104 by the encapsulating material 116. In the prior art mold systems, such action forces the air pocket 110 to change shape and location and may eventually cause the prior art semiconductor component 106 to buckle up toward the mold lid 104. In contrast, and as can be seen in the sequence from the first condition of FIG. 1A to the second condition of FIG. 1B, the air pocket 120 volume in the mold system 100 actually reduces as the encapsulating material 116 fills the mold cavity 112. The air pocket 120 shrinks because the vent channel 118 vents gas from the mold cavity 112 by allowing the gas to flow in the exhaust direction (arrow 132). Therefore, unwanted buckling of the semiconductor component 102 may be avoided, particularly when a vacuum is applied through the vent channel 118 to urge a flexible semiconductor component 102 toward the mold base 104.

This venting or exhausting effect may be emphasized by locating the vent channel(s) 118 at a side of the mold cavity 112 spaced apart from, even opposite, the side from which the encapsulating material 116 is supplied. For example, when the encapsulating material 116 is supplied from the first mold cavity side 126, the vent channel(s) 118 may be located proximate the second mold cavity side 128.

It is contemplated that a similar effect within the mold cavity 112 to that provided by the vest channel 118 and vacuum source may be instead provided by a pressure channel and pressure source (not shown). That is, instead of evacuating air from beneath the semiconductor component 102 aid the mold base 104, the combination of the pressure channel and pressure source may supply air or another working fluid (such as an inert gas) to the mold cavity 112 between the semiconductor component 102 and the lid surface 108 to force the semiconductor component 102 down into contact with the base surface 106. In such an alternate arrangement, the vent channel(s) 118 can still be present in an area of the mold cavity 112 from which gases are desired to be evacuated. Additionally, such a pressurized mold cavity 112 requires that the entering encapsulating material 116 be supplied under pressure, and the relative pressures of the mold cavity 112 and the encapsulating material 116 may need to be regulated as the mold cavity fills with encapsulating material. One of ordinary skill in the art could readily design a pressurized system for a particular application of the present invention.

While aspects of the present invention have been particularly shown and described with reference to the preferred embodiment above, it will be understood by those of ordinary skill in the art that various additional embodiments may be contemplated without departing from the spirit and scope of the present invention. For example, the mold system 100 or portions thereof may be made of any materials and in any size, shape, and/or configuration. An existing mold system could be retrofitted with vent channels 118 according to the present invention. Some feature could be provided to the semiconductor component 102 to supplement or replace the function of the vent channel 118. A device or method incorporating any of these features should be understood to fall under the scope of the present invention as determined based upon the claims below and any equivalents thereof.

Having described the invention we claim the following:

1. A mold system for forming a mold cap on a semiconductor component, the mold system comprising:
a mold base and a mold lid that together define a mold cavity, the mold base supporting the semiconductor component within the mold cavity, the semiconductor component defining a component footprint and footprint periphery on the mold base;
a supply channel provided in the mold lid for supplying an encapsulating material to the mold cavity; and
at least one vent channel provided in the mold base, the vent channel intersecting the footprint periphery to vent gas trapped between the semiconductor component and the mold base from the mold cavity when the encapsulating material is supplied to the mold cavity.

2. The mold system of claim 1, wherein the vent channel provides a vacuum source in fluid communication with the mold cavity, the vacuum source urging the gas toward the vent channel.

3. The mold system of claim 1, wherein the vacuum source urges the semiconductor component into contact with the mold base when the gas has been substantially evacuated from between the semiconductor component and the mold base.

4. The mold system of claim 1, wherein a portion of the semiconductor component protrudes from the mold cavity.

5. The mold system of claim 1, wherein at least one of the semiconductor component and the encapsulating material generate at least a portion of the gas vented by the vent channel.

6. The mold system of claim 1 wherein the supply channel supplies encapsulating material to the mold cavity from a first mold cavity side, the encapsulating material flows through the mold cavity toward a second mold cavity side spaced apart from the first mold cavity side, and at least one vent channel is located proximate the second mold cavity side.

7. A method of encapsulating semiconductor components, the method comprising the steps of:
defining a mold cavity between a mold lid and a mold base;
substantially enclosing the semiconductor component within the mold cavity;
defining a component footprint and a footprint periphery on the mold base with the semiconductor component;
locating at least one vent channel in at least one of the mold lid and the mold base, the vest channel intersecting the footprint periphery;
supplying an encapsulating material to the mold cavity; and
venting gas trapped between the semiconductor component and the mold base from the mold cavity when the encapsulating material is supplied to the mold cavity.

8. The method of claim 7, wherein the step of venting gas trapped between the semiconductor component and the mold base from the mold cavity when the encapsulating material is supplied to the mold cavity includes the steps of:
placing a vacuum source in fluid communication with the mold cavity through the vent channel;
actuating the vacuum source; and
urging the gas toward the vent channel under vacuum.

9. The method of claim 8, including the steps of:
substantially evacuating the gas from between the semiconductor component and the mold base;
actuating the vacuum source; and
urging the semiconductor component into contact with the mold base under vacuum.

10. The method of claim 8, wherein the step of substantially enclosing the semiconductor component within the mold cavity includes the step of permitting a portion of the semiconductor component to protrude from the mold cavity.

11. The method of claim 8, including the step of generating at least a portion of the gas with at least one of the semiconductor component and the encapsulating material.

12. The method of claim 8, wherein the step of supplying an encapsulating material to the mold cavity includes the steps of:
supplying encapsulating material to the mold cavity from a first mold cavity side;
directing the encapsulating material to flow through the mold cavity toward a second mold cavity side spaced apart from the first cavity side; and
venting gas from the mold cavity through at least one vent channel formed in the mold base proximate the second mold cavity side.

13. A mold system for forming a mold cap on a semiconductor component, the mold system comprising:
a mold base and a mold lid that together define a mold cavity, the mold base supporting the semiconductor component within the mold cavity, die semiconductor component defining a component footprint and footprint periphery on the mold base;
at least one vent channel provided in the mold base, the vent channel intersecting the footprint periphery to vent gas trapped between the semiconductor component and the mold base from the mold cavity when the encapsulating material is supplied to the mold cavity.

14. The mold system of claim 13, the mold based including a plurality of vent channels arranged about the periphery of the mold base, each vent channel intersecting the footprint periphery to vent gas trapped between the semiconductor component and the mold base.

15. The mold system of claim 14, each vent channel having a depth of about 5 μm to about 50 μm.

16. The mold system of claim 13, the vent channel providing a vacuum source in fluid communication with the mold cavity, the vacuum source urging the gas toward the vent channel.
